(19) United States
(12) Patent Application Publication
(10) Pub. No.: US 2008/0165818 A1
(43) Pub. Date: Jul. 10, 2008

(54) Semiconductor optical device

(75) Inventor: Jun-ichi Hashimoto, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(73) Assignee: SUMITOMO ELECTRIC INDUSTRIES, LTD.

(21) Appl. No.: 11/785,667

(22) Filed: Apr. 19, 2007

(30) Foreign Application Priority Data
Apr. 27, 2006 (JP) P2006-124122

(51) Int. Cl. H01S 5/323

(52) U.S. Cl. 372/43.01

(57) ABSTRACT

A semiconductor optical device includes an active layer made of III-V compound semiconductor containing Ga, As and N; a diffraction grating layer which is made of III-V compound semiconductor and is provided on the active layer; and a cladding layer which is made of III-V compound semiconductor and is provided on the diffraction grating layer, wherein the refractive index of the cladding layer is smaller than the refractive index of the diffraction grating layer.

### BACKGROUND OF THE INVENTION

1. Field of the Invention

The present invention relates to a semiconductor optical device.

2. Related Background Art

Distributed feedback semiconductor lasers (DFB lasers) are known, in which an active layer made of GaInNAs is provided on a GaAs substrate, a diffraction grating layer made of AlGaInP is provided on this active layer, and a cladding layer made of GaAs is provided on this diffraction grating layer (see Laid-open Japanese Patent Application No. H11-74607).

### SUMMARY OF THE INVENTION

In the DFB laser as described above, the band gap energy of the cladding layer is set to be smaller than the band gap energy of the diffraction grating layer. Consequently, the refractive index of the cladding layer is larger than the refractive index of the diffraction grating layer. Consequently, light leaks from the diffraction grating layer into the cladding layer, so strong confinement of light into the diffraction grating layer cannot be achieved and only a small optical confinement factor is obtained. As a result, the coupling coefficient cannot be increased, so satisfactory lasing performance of the DFB laser is not obtained.

The present invention was made in view of the above circumstances, its object being to provide a semiconductor optical device of highlight emission efficiency.

In order to solve the problem described above, a semiconductor optical device according to the present invention comprises: an active layer made of III-V compound semiconductor containing Ga, As and N; a diffraction grating which is made of III-V compound semiconductor and is provided on the active layer; and a cladding layer which is made of III-V compound semiconductor and is provided on the diffraction grating layer, in which the refractive index of the cladding layer is smaller than the refractive index of the diffraction grating layer.

### BRIEF DESCRIPTION OF THE DRAWINGS

FIG. 1 is a cross-sectional view showing schematically a semiconductor optical device according to a first embodiment;

FIG. 2 is a cross-sectional view showing schematically a semiconductor optical device according to a second embodiment;

FIG. 3 is a cross-sectional view showing an example of the structure of a III-V compound semiconductor layer;

FIG. 4 is a cross-sectional view showing schematically a semiconductor optical device according to a third embodiment;

FIG. 5 is a cross-sectional view showing schematically a semiconductor optical device according to a fourth embodiment;

FIG. 6 is a graph showing the relationship between the thickness d of a diffraction grating layer and the coupling coefficient κ of a semiconductor optical device according to a fourth embodiment;

FIG. 7 is a perspective view showing schematically a semiconductor optical device according to a fifth embodiment;

FIG. 8 is a cross-sectional view along the line VIII-VIII shown in FIG. 7;

FIGS. 9A to 9C are cross-sectional views showing schematically steps in a method of manufacture of a semiconductor optical device according to a fifth embodiment; and

FIGS. 10A to 10C are views showing schematically steps in a method of manufacture of a semiconductor optical device according to the fifth embodiment.

### DESCRIPTION OF THE PREFERRED EMBODIMENTS

Embodiments of the present invention are described in detail below with reference to the appended drawings. In the description of the drawings, elements that are the same or identical are given the same reference symbols to avoid duplication of description.

### First Embodiment

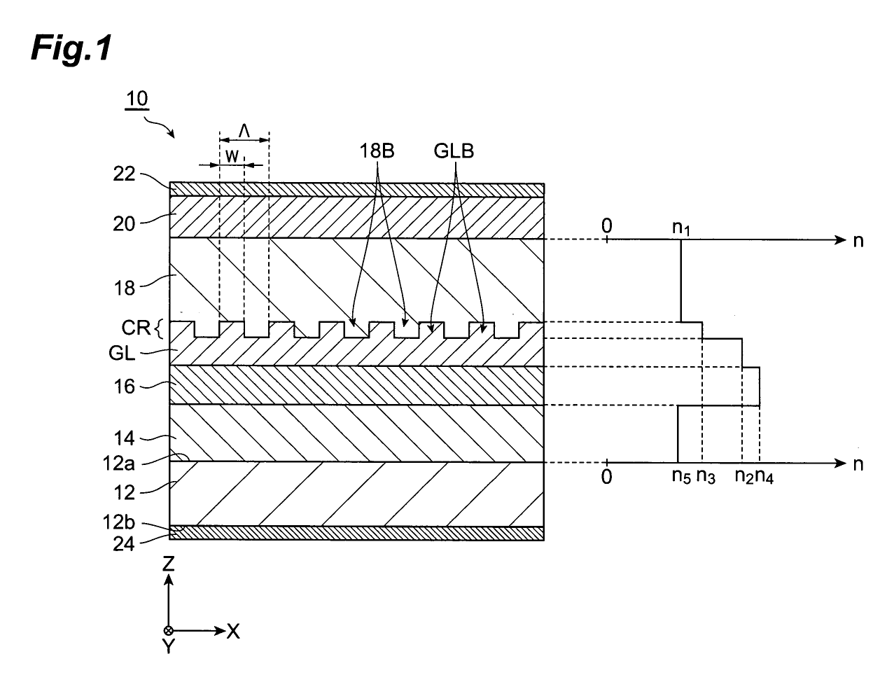

FIG. 1 is a cross-sectional view showing schematically a semiconductor optical device according to a first embodiment. In FIG. 1, the X axis, Y axis and Z axis indicate three-dimensional space. FIG. 1 also shows the refractive index profile of a semiconductor optical device according to the first embodiment. The axis n indicates the magnitude of the refractive index.

The semiconductor optical device 10 shown in FIG. 1 comprises: a GaAs substrate 12 of first conductivity type (for example n type); a cladding layer 14 of first conductivity type provided on the surface 12a of the GaAs substrate 12; an active layer 16 provided on the cladding layer 14; a diffraction grating layer GL of second conductivity type (for example p type) provided on the active layer 16; and a cladding layer 18 of second conductivity type provided on the diffraction grating layer GL. The cladding layer 14, active layer 16, diffraction grating layer GL and cladding layer 18 all comprise III-V compound semiconductor. The surface 12a of the GaAs substrate 12 extends substantially parallel with the XY plane. Consequently, the thickness direction of the GaAs substrate 12 is the Z axis direction.

On the cladding layer 18 there is preferably provided in this order a contact layer 20 of second conductivity type and electrode 22. Thanks to the contact layer 20, ohmic contact of the electrode 22 can be achieved. Preferably an electrode 24 is provided on the face (back face) 12b on the opposite side to the front face 12a of the GaAs substrate 12. The semiconductor optical device 10 may be for example a distributed feedback semiconductor laser (DFB laser) of oscillation wavelength of longer than 1 μm that is used for example for optical communication. In this case, single mode oscillation is possible.

Preferably the GaAs substrate 12 comprises a bulk substrate obtained by slicing for example a GaAs ingot and a GaAs buffer layer grown on this bulk substrate. In this case, the upper surface of the GaAs buffer layer is the upper surface 12a of the GaAs substrate 12.

As the material of the cladding layer 14, there may be employed for example AlGaInP or GaInP lattice-matched to GaAs. In one embodiment, the cladding layer 14 is made of n-AlGaInP lattice-matched to GaAs. The band gap energy of the AlGaInP lattice-matched to GaAs may be selected in the range of about 1.9 to 2.3 eV (1 eV=1.6×10⁻¹⁹ J) depending on its composition. The band gap energy of GaInP lattice-matched to GaAs is about 1.9 eV.

The cladding layer 14 is made of for example AlGaAs or GaInAsP lattice-matched to GaAs. The band gap energy of the AlGaAs lattice-matched to GaAs may be selected in the range of about 1.42 to 2.16 eV depending on its composition. The band gap energy of the GaInAsP lattice-matched to GaAs may be selected in the range of about 1.42 to 1.9 eV depending on its composition. By adjusting the composition ratios of the material of the cladding layer 14, the band gap energy and refractive index n₅ of the cladding layer 14 can be adjusted.

If the cladding layer 14 is made of high band gap material such as AlGaInP, GaInP, AlGaAs, or GaInAsP, the band gap difference between the cladding layer 14 and the active layer 16 can be made large, so confinement of the carriers into the active layer 16 can be improved. As a result, the light emission efficiency of the semiconductor optical device 10 can be raised.

The active layer 16 may have any of a bulk structure, single quantum well structure (SQW) or multiple quantum well structure (MQW). If for example the active layer 16 has a multiple quantum well structure, the active layer 16 may be made of barrier layers and well layers alternately stacked.

The active layer 16 includes Ga, As and N. As the material of the active layer 16, there may be mentioned by way of example GaInNAs or GaNAs. The band gap energy and refractive index n₄ of the active layer 16 may be adjusted by adjusting the composition ratios of the material of the active layer 16. In one embodiment, the active layer 16 is obtained by alternately stacking GaAs barrier layers of thickness 8 nm, and Ga_{0.65}In_{0.35}N_{0.006}As_{0.994} well layers of thickness 7 nm.

By adjusting the composition ratios, the lattice constant of the III-V compound semiconductor material containing Ga, As and N can be set to a lattice constant that is the same as or close to the lattice constant of the GaAs substrate 12. Consequently, defects caused by lattice mismatching are not produced, so an active layer 16 of excellent crystal properties can be grown on the substrate 12. The band gap energy of the III-V compound semiconductor material containing Ga, As and N normally corresponds to a luminescence wavelength of more than 1 μm. If such a III-V compound semiconductor material is employed for the active layer 16, an oscillation wavelength in the long wavelength region of more than 1 μm can easily be realized. A light source for optical communication in for example from 1 to 1.6 μm wavelength region can therefore be manufactured. Since GaAs is transparent to the light of this wavelength region, such light is not absorbed by the GaAs substrate 12.

Also, at least one of Sb and P may be added to the GaInNAs or GaNAs. Sb functions as a so-called surfactant, suppressing three-dimensional growth of the GaInNAs or GaNAs. The crystal quality of the GaInNAs or GaNAs can thereby be improved. P reduces the amount of local crystal distortion of the GaInNAs or GaNAs. The crystal quality of the GaInNAs or GaNAs can thereby be improved. Also, P increases the content of N that is incorporated in the crystal when crystal growth is performed.

As examples of III-V compound semiconductor materials containing N, Ga and As and to which at least one of Sb or P has been added, there may be mentioned by way of example GaNAsSb, GaNAsP, GaNAsSbP, GaInNAsSb, GaInNAsP or GaInNAsSbP. By adjusting the composition ratios, the lattice constants of these III-V compound semiconductor materials can be set to a lattice constant that is the same as or close to the lattice constant of the GaAs substrate 12. Consequently, defects due to lattice mismatching are not produced, so an active layer 16 of excellent crystal properties can be grown on the substrate 12.

The diffraction grating layer GL has a plurality of convex sections GLB arranged in the X axis direction with a prescribed pitch Λ. A Bragg-type diffraction grating is constituted by the convex sections GLB. The diffraction grating is formed on the side of the cladding layer 18. The width W of the convex sections GLB is for example half the pitch Λ.

As the material of the diffraction grating layer GL, there may be mentioned for example GaAs, AlGaAs, or GaInAsP. By adjusting the composition ratios of the material of the diffraction grating layer GL, the band gap energy and refractive index n₂ of the diffraction grating layer GL can be adjusted. In one embodiment, the diffraction grating layer GL is made of p-GaAs.

In particular, if AlGaAs or GaInAsP is employed as the material of the diffraction grating layer GL, the band gap energy of the diffraction grating layer GL can be made larger and the refractive index n₂ of the diffraction grating layer GL can be made smaller than in the case where GaAs is employed for the diffraction grating layer GL. Consequently, light and carriers can be more strongly confined in the active layer 16 than in the case where GaAs is employed.

Preferably also the diffraction grating layer GL is made of an Al-free material. In this case, Al oxidation at the diffraction grating layer GL cannot occur. Consequently, generation of crystal defects due to Al oxidation can be suppressed. As a result, the long-term reliability of the semiconductor optical device 10 can be improved.

The cladding layer 18 may comprise buried sections 18B buried between the convex sections GLB of the diffraction grating layer GL. In this case, a coupling region CR may be formed by the convex sections GLB of the diffraction grating layer GL and the buried sections 18B of the cladding layer 18.

Preferably the cladding layer 18 is made of semiconductor material lattice-matched to GaAs: for example AlGaInP or GaInP, lattice-matched to GaAs, may be employed. The band gap energy and refractive index n₁ of the cladding layer 18 can be adjusted by adjusting the composition ratios of the material of the cladding layer 18. In one embodiment, the cladding layer 18 is made of p-AlGaInP.

The case may also be considered in which the diffraction grating layer GL is made of GaAs, and the cladding layer 18 is made of AlGaInP lattice-matched to GaAs. Such AlGaInP lattice-matched to GaAs may be represented by: (AlₓGa₁₋ₓ)_{0.5}In_{0.5}P(O≦x≦1). The refractive index n₁ of the cladding layer 18 can be made smaller when the Al composition ratio x is increased. Consequently, if the Al composition ratio x is made 0, i.e. if the cladding layer 18 comprises Ga_{0.5}In_{0.5}P, the refractive index n₁ of the cladding layer 18 is a maximum. Even in this case, the refractive index n₁ of the Ga_{0.5}In_{0.5}P cladding layer 18 is smaller than the refractive index n₂ of the GaAs diffraction grating layer GL.

For example, whereas the refractive index n₁ of a Ga_{0.5}In_{0.5}P cladding layer 18 for light of the 1.3 μm wavelength region is about 3.2, the refractive index n₂ of the GaAs diffraction grating layer GL is about 3.4. Consequently, even if Ga_{0.5}In_{0.5}P, for which the refractive index of the cladding layer 18 is a maximum, is employed, a sufficiently large refractive index difference of about 0.2 is obtained between the cladding layer 18 and the diffraction grating layer GL. Furthermore, if the Al composition ratio x in the AlGaInP cladding layer 18 is increased, the refractive index of the cladding layer 18 is lowered, so the refractive index difference can be made even larger.

Preferably the contact layer 20 is made of III-V compound semiconductor of lower band gap than the cladding layer 18, in order to form ohmic contact with the electrode 22. In one embodiment, the contact layer 20 is made of p+-GaAs.

When the cladding layer 14, active layer 16, diffraction grating layer GL, cladding layer 18 and contact layer 20 are formed, for example a vapor phase growth method such as an OMVPE method or MBE method may be employed. In addition, when forming the diffraction grating layer GL, preferably for example a photolithographic method is employed.

Also, as shown in FIG. 1, the refractive index n₁ of the cladding layer 18 is smaller than the refractive index n₂ of the diffraction grating layer GL. Since the refractive index changes periodically in the X axis direction in the coupling region CR, the refractive index n₃ of the coupling region CR is expressed as an average refractive index. The refractive index n₃ of the coupling region CR is a value between the refractive index n₁ of the cladding layer 18 and the refractive index n₂ of the diffraction grating layer GL. It should be noted that the “average refractive index” may be expressed as follows, where, in the following formula, W represents the width of the convex sections of the diffraction grating layer GL and Λ represents a pitch (one period) of the diffraction grating layer GL.

n₃={n₂²+(n₁²−n₂²)(1−W/Λ))}^{1/2}

The refractive index n₄ of the active layer 16 is larger than both the refractive index n₂ of the diffraction grating layer GL and the refractive index n₅ of the cladding layer 14. In this way, the waveguide light is strongly confined in the active layer 16.

Also, the band gap energies of the cladding layer 14 and the diffraction grating layer GL are both larger than the band gap energy of the active layer 16. Consequently, carriers that are injected into the active layer 16 are confined within the active layer 16. As a result, light and carriers are confined within the active layer 16 and stimulated emission due to mutual interaction of the light and carriers occurs effectively. The refractive index n₁ of the cladding layer 18 and the refractive index n₅ of the cladding layer 14 may have the same value.

The coupling coefficient κ that indicates the magnitude of coupling of the forwardly propagating light wave with backwardly propagating light wave in the diffraction grating of the DFB laser is expressed by the following equation (1):

κ=(k²/2β)(n₂²−n₁²)Γ_{g} sin(q a π)/qπ (1)

where, in equation (1), k is the wave number represented by the following equation (2), β is the propagation coefficient of the oscillation mode within the laser, n₁ is the refractive index of the cladding layer 18, n₂ is the refractive index of the diffraction grating layer GL, Γ_{g} is the optical confinement factor of the coupling region CR, q is the diffraction grating order, and a represents the duty ratio expressed by the following equation (3):

k=2π/λ₀ (2)

where, in equation (2), λ₀ represents the oscillation wavelength in vacuum.

a=W/Λ (3)

where, in equation (3), W represents the width of the convex sections of the diffraction grating layer GL and Λ represents a pitch (one period) of the diffraction grating layer GL.

In order to improve the oscillation performance of a DFB laser, is necessary to increase the coupling coefficient κ described above. From the above equation (1), in order to make the coupling coefficient κ large, it is desirable to increase the difference of squares of the refractive indices (n₂²−n₁²) and the optical confinement factor Γ_{g}. In order to increase the optical confinement factor Γ_{g}, it is necessary to make the refractive index n₁ of the cladding layer 18 significantly smaller than the refractive index n₂ of the diffraction grating layer GL.

Since, with the semiconductor optical device 10 according to this embodiment, the refractive index n₁ of the cladding layer 18 is smaller than the refractive index n₂ of the diffraction grating layer GL, (n₂²−n₁²) and the optical confinement factor Γ_{g} can be increased. Consequently, from the above equation (1), the coupling coefficient κ can be made larger, so that in the semiconductor optical device 10, strong coupling of the forwardly propagating light wave with backwardly propagating light wave in the diffraction grating layer GL can be achieved. Since the refractive index (n₁) of the cladding layer 18 is smaller than that (n₂) of the diffraction grating layer GL, the leakage of the waveguiding light from the grating layer GL into the cladding layer 18 can be suppressed effectively. Consequently, it becomes possible to strongly confine the light in the diffraction grating layer GL. As a result, the oscillation threshold current is lowered, and excellent DFB laser oscillation is obtained.

### Second Embodiment

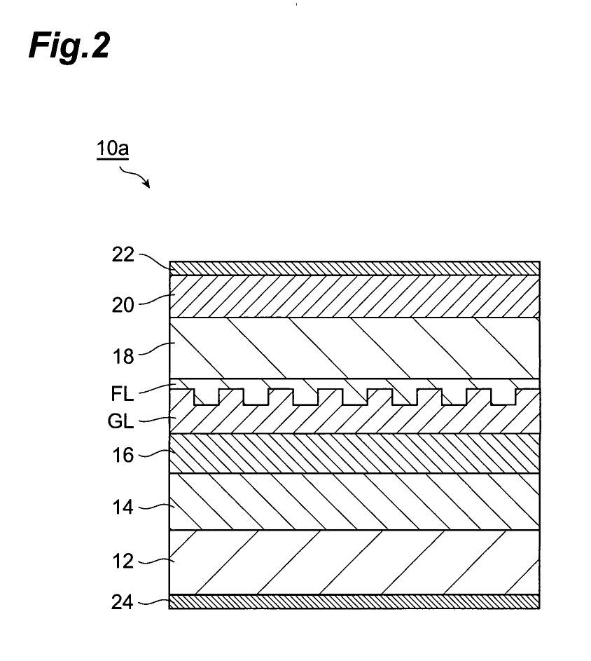

FIG. 2 is a cross-sectional view showing schematically a semiconductor optical device according to a second embodiment. The semiconductor optical device 10a shown in FIG. 2 further comprises, in addition to the structure of the semiconductor optical device 10 of the first embodiment, a III-V compound semiconductor layer FL (first intermediate layer). The III-V compound semiconductor layer FL is provided between the diffraction grating layer GL and the cladding layer 18.

With the semiconductor optical device 10a, the same beneficial effects are obtained as in the case of the semiconductor optical device 10 according to the first embodiment. In the case of the semiconductor optical device 10, the cladding layer 18 was directly grown on the diffraction grating layer GL. However, when growing on such an uneven surface of the grating layer GL, source materials cannot be supplied uniformly on the GaAs substrate due to the local change at the configuration of the grating layer GL, which varies the local growth conditions. In addition, growth condition may fluctuate depending on the crystallographic orientation of the underlayer. Consequently, growth condition may deviate from the lattice-matching condition, and thus lattice-mismatching may occur, which would generate defects in the cladding layer 18. Such defects impair the laser performance and reliability and are therefore undesirable. In contrast, in the case of the semiconductor optical device 10a, the uneven surface of the diffraction grating layer GL is made to be flat by the III-V compound semiconductor layer FL. When a cladding layer 18 is grown on this flattened surface, it is not subject to bad effects from the underlayer as described above, so growth can be performed while maintaining excellent lattice matching conditions over the entire wafer surface. Consequently, when the cladding layer 18 is formed on the III-V compound semiconductor layer FL, the crystal properties of the cladding layer 18 can be improved compared with the case where the cladding layer 18 is formed on an uneven surface.

Also, preferably the III-V compound semiconductor layer FL comprises AlGaAs. Since AlGaAs of any composition can be lattice-matched to GaAs, crystal defects due to lattice mismatching are not produced in the III-V compound semiconductor layer FL. Consequently, even in the case where there is local fluctuation of the composition of the AlGaAs in the III-V compound semiconductor layer FL in the vicinity of the uneven surface of the diffraction grating layer GL, due to local variations in the supply of the source materials or to differences in the crystallographic orientation of the underlayer, lattice matching conditions are maintained and a III-V compound semiconductor layer FL of excellent crystal properties is obtained.

Also, by suitable adjustment of the Al composition ratio of the AlGaAs, it is possible to make the refractive index of the III-V compound semiconductor layer FL significantly smaller than the refractive index n₂ of the diffraction grating layer GL. As a result, it becomes possible to strongly confine the light within the diffraction grating layer GL and the coupling coefficient κ can be increased, so the oscillation threshold current is lowered, and excellent DFB laser oscillation is obtained.

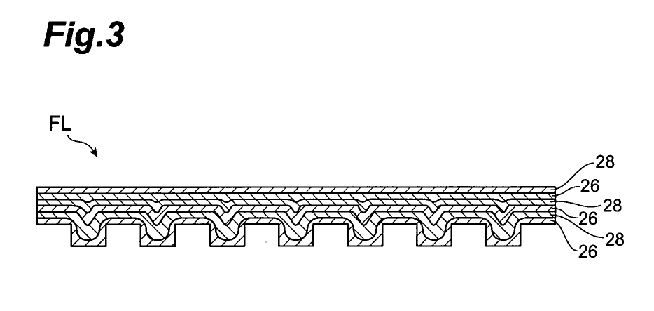

FIG. 3 is a cross-sectional view showing an example of the structure of a III-V compound semiconductor layer FL. As shown in FIG. 3, the III-V compound semiconductor layer FL may contain first semiconductor layers 26 and second semiconductor layers 28 alternately stacked. The III-V compound semiconductor layer FL may have a multi-layer film structure.

In this case also, since the cladding layer 18 is grown after the uneven surface of the diffraction grating layer GL has been made to be flat by the III-V compound semiconductor layer FL of multi-layer film structure, for the same reasons as described above, the crystal properties of the cladding layer 18 can be improved compared with the case where a cladding layer 18 is directly grown on the uneven surface. Also, the band gap energy of the semiconductor layers 26 may be different from the band gap energy of the semiconductor layers 28. In this case, propagation of crystal defects can easily be stopped at the interfaces of the semiconductor layers 26 and semiconductor layers 28. Consequently, propagation of crystal defects present at the uneven surface of the diffraction grating layer GL can easily be stopped, so the crystal properties of the cladding layer 18 can be further improved.

Preferably the III-V compound semiconductor layer FL has a superlattice structure. Also in this case, growth condition may deviate from the lattice-matched condition due to the local fluctuation of the source material supply, and due to the differences in crystallographic orientation of the underlayer as mentioned before, which may generate lattice-mismatch. However, in this case, the thicknesses of the semiconductor layers 26 and semiconductor layers 28 may be for example a few nm in each case, so that the thicknesses of the semiconductor layers 26, 28 are sufficiently thinner than the critical thickness. Therefore, even if the lattice-mismatch occurs, crystal defects caused by such lattice mismatch are not produced because the thicknesses of semiconductor layers 26, 28 are much below the critical thickness. Excellent crystal properties of the III-V compound semiconductor layer FL can therefore be maintained.

The semiconductor layers 26 and semiconductor layers 28 may mutually comprise the same material. In this case, the composition ratio of the material of the semiconductor layers 26 differs from the composition ratio of the material of the semiconductor layers 28. As examples of such materials, there may be mentioned AlGaInP, AlGaAs, or GaInAsP. Also, the semiconductor layers 26 and semiconductor layers 28 may be made of mutually different materials. Examples of such material combinations include: AlGaInP/GaInP, AlGaInP/GaInAsP, GaInP/GaInAsP, AlGaInP/GaAs, GaInP/GaAs, AlGaAs/GaAs, and GaInAsP/GaAs.

The refractive index of the III-V compound semiconductor layer FL can be made significantly smaller than the refractive index n₂ of the diffraction grating layer GL by adjusting the composition ratio of the semiconductor layers 26 and semiconductor layers 28. Light can therefore be more strongly confined in the diffraction grating layer, which makes it possible to increase the coupling coefficient κ: the oscillation of threshold current is thereby lowered, with the result that excellent DFB laser oscillation is obtained. Also, Al-free material can be employed as the material of the semiconductor layers 26 and semiconductor layers 28, so that the bad effect of oxidation of Al can be removed. In addition, when selecting the material of the semiconductor layers 26 and semiconductor layers 28, a large number of material combinations can be chosen, so that the structure of the semiconductor optical device 10a can be designed more freely.

### Third Embodiment

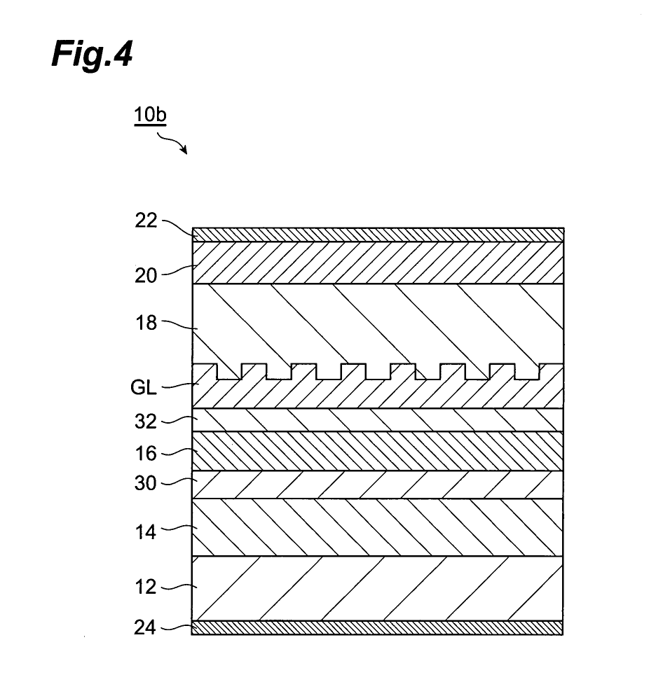

FIG. 4 is a cross-sectional view showing schematically a semiconductor optical device according to a third embodiment. In addition to the structure of the semiconductor optical device 10 according to the first embodiment, the semiconductor optical device 10b shown in FIG. 4 comprises: an optical confinement layer 30 provided between the active layer 16 and the cladding layer 14; and an optical confinement layer 32 provided between the active layer 16 and the diffraction grating layer GL. Preferably the optical confinement layers 30, 32 are made of undoped III-V compound semiconductor. The optical confinement layer 30 may be of first conductivity type. The optical confinement layer 32 may be of second conductivity type.

The same beneficial effect as in the case of the semiconductor optical device 10 according to the first embodiment is obtained with the semiconductor optical device 10b. In addition, more light can be confined in the active layer 16, thanks to the optical confinement layers 30, 32. Consequently, a better DFB laser performance is obtained than in the case of the semiconductor optical device 10 according to the first embodiment.

Preferably the band gap energy of the optical confinement layer 30 is between the band gap energy of the cladding layer 14 and the band gap energy of the active layer 16. If this is the case, when carriers are injected into the active layer 16 from the cladding layer 14, the optical confinement layer 30 does not constitute a barrier. Likewise, preferably the band gap energy of the optical confinement layer 32 is between the band gap energy of the diffraction grating layer GL and the band gap energy of the active layer 16. If this is the case, when carriers are injected into the active layer 16 from the cladding layer 18, the optical confinement layer 32 does not constitute a barrier.

Also, preferably the refractive index of the optical confinement layer 30 is between the refractive index n₅ of the cladding layer 14 and the refractive index n₄ of the active layer 16, and preferably the refractive index of the optical confinement layer 32 is between the refractive index n₂ of the diffraction grating layer GL and the refractive index n₄ of the active layer 16. If this is the case, the cladding layer 14 and the diffraction grating layer GL act so as to confine the light generated in the active layer 16 into the active layer 16, the optical confinement layer 30 and optical confinement layer 32: as a result, optical confinement into the active layer 16 is strengthened. In particular, if the active layer 16 has a quantum well structure, the optical confinement factor can be increased by the optical confinement layers 30, 32.

As a material that may be used for the optical confinement layers 30, 32, there may be mentioned the III-V compound semiconductor material containing N, Ga and As shown as the active layer material in the first embodiment. The optical confinement layers 30, 32 may be made of for example AlGaAs, GaAs, GaInAs, or GaInAsP. These have a lattice constant that is the same as or close to the lattice constant of the GaAs. Consequently, since no defects caused by lattice mismatching are produced, optical confinement layers 30, 32 of the excellent crystal properties can be grown on the GaAs substrate 12. However, it is necessary to suitably adjust the composition so that the band gap energies and refractive indices of the optical confinement layers 30, 32 to which these materials are applied have the desired values.

### Fourth Embodiment

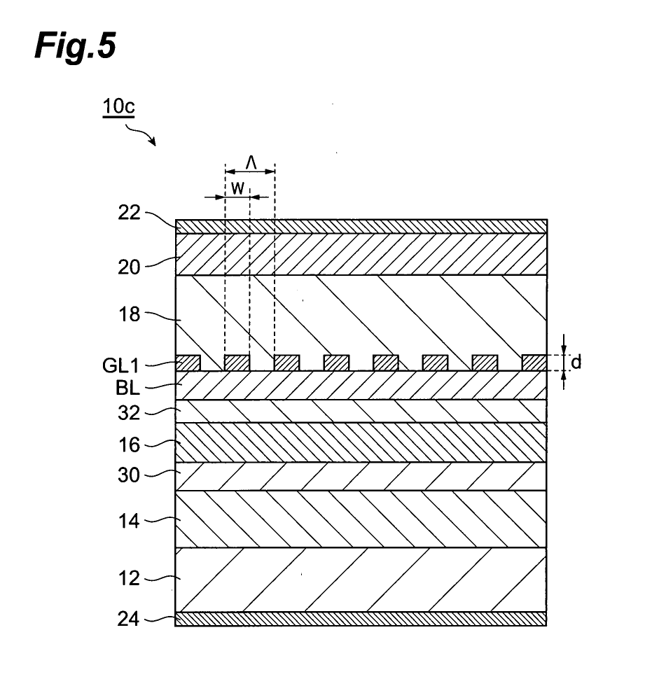

FIG. 5 is a cross-sectional view showing schematically a semiconductor optical device according to a fourth embodiment. In the semiconductor optical device 10c shown in FIG. 5, the diffraction grating layer GL in the semiconductor optical device 10b according to the third embodiment is replaced by a diffraction grating layer GL1. The diffraction grating layer GL1 has the same shape as the convex sections GLB of the diffraction grating layer GL. As the material of the diffraction grating layer GL1, there may be mentioned by way of example the same material as that of the diffraction grating layer GL. The same beneficial effect as in the case of the semiconductor optical device 10 according to the first embodiment is obtained with the semiconductor optical device 10c.

In addition, the semiconductor optical device 10c comprises an intermediate layer BL (second intermediate layer) which is made of III-V compound semiconductor and is provided between the active layer 16 and the diffraction grating layer GL1. Preferably the intermediate layer BL is made of a III-V compound semiconductor of second conductivity type. As the material of the intermediate layer BL, there may be mentioned by way of example GaInP, AlGaInP or GaInAsP. The intermediate layer BL may be a single layer or may be multiple layers. Also, the intermediate layer BL may have a superlattice structure.

Preferably the refractive index of the intermediate layer BL is smaller than the refractive index of the diffraction grating layer GL1. In this case, in addition to the cladding layer 18, the intermediate layer BL also has a function of confining light within the diffraction grating layer GL1, so that, compared with the semiconductor optical device 10, in which only the cladding layer 18 is of lower refractive index than the diffraction grating layer GL, the light can be confined within the diffraction grating layer GL1 more strongly, and a larger coupling coefficient is obtained. Consequently, the oscillation performance of the DFB laser can be further improved.

Also, when a prescribed etchant is employed, the etching rate of the intermediate layer BL is preferably smaller than the etching rate of the diffraction grating layer GL1. In this case, when the diffraction grating layer GL1 is formed by etching using this etchant, the intermediate layer BL can be employed as an etching stop layer. In this way, the uniformity with position and the reproducibility of the depth (height) of the groove of the diffraction grating layer GL1, i.e. the thickness d of the diffraction grating layer GL1, can be improved. Consequently, since reproducibility and uniformity with position of the coupling coefficient is improved, the reproducibility of the semiconductor laser performance and the yield of semiconductor lasers are improved. If for example the diffraction grating layer GL1 comprises GaAs or AlGaAs, and the intermediate layer BL comprises GaInP, AlGaInP or GaInAsP, the etching rate of the intermediate layer BL is very considerably smaller than that of the diffraction grating layer GL1 by using a phosphoric acid-based etchant, so that the intermediate layer BL can be employed as an etching stop layer. Also, if for example the diffraction grating layer GL1 comprises GaInAsP and a phosphoric acid-based etchant is employed the intermediate layer BL made of GaInP or AlGaInP can be used as an etching stop layer.

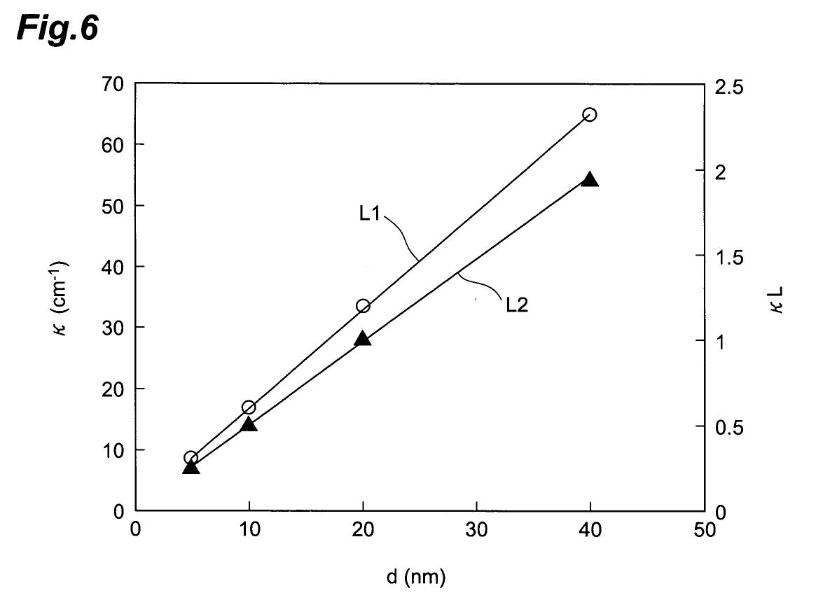

FIG. 6 is a graph showing the relationship between the thickness d of the diffraction grating layer GL1 of the semiconductor optical device 10c and the coupling coefficient κ. The relationship between the product κL of the coupling coefficient κ and the cavity length L and the thickness d of the diffraction grating layer GL1 is also shown in the graph shown in FIG. 6. The straight line L1 shown in FIG. 6 shows an example of the results of calculation of the coupling coefficient κ. Also, the straight line L2 shows an example of the results of calculation of the product κL. The following structural parameters were employed in the calculation:

cladding layer 14: GaInP layer lattice-matched to GaAs; optical confinement layers 30, 32: undoped GaAs layers of thickness 140 nm;
active layer 16: double quantum well structure (GaInNAs well layer of thickness 7 nm, GaAs layer of thickness 8 nm);
intermediate layer BL: p-GaInP layer of thickness 20 nm;
diffraction grating layer GL1: p-GaAs layer
cladding layer 18: GaInP layer lattice-matched to GaAs;
cavity length L: 300 μm; and
duty ratio (W/Λ) of diffraction grating layer GL1: 0.5.

As shown in FIG. 6, even when the thickness d of the diffraction grating layer GL1 is small, such as not more than 40 nm, the coupling coefficient κ shows a large value of a few tens of cm⁻¹. Further, if the thickness d of the diffraction grating layer GL1 is from 20 to 40 nm, a sufficiently large values between 1 and 2 are obtained with the product κL. The reason why a sufficient coupling coefficient is obtained with this structure even when the diffraction grating layer GL1 is as thin as this is that the optical confinement factor (Γ_{g} in equation (1)) of the diffraction grating layer GL1 can be increased by sandwiching the diffraction grating layer GL1 between the GaInP layers whose refractive index is smaller than that of the grating layer GL1, and that refractive index difference (n₂²−n₁² in equation (1)) between the GaAs diffraction grating layer GL1 and p-GaInP cladding layer 18 is significantly large.

### Fifth Embodiment

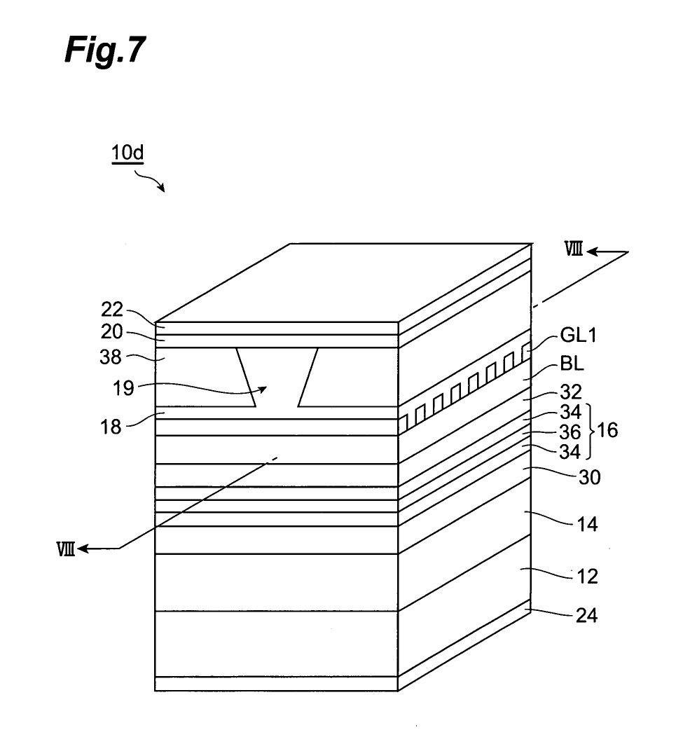

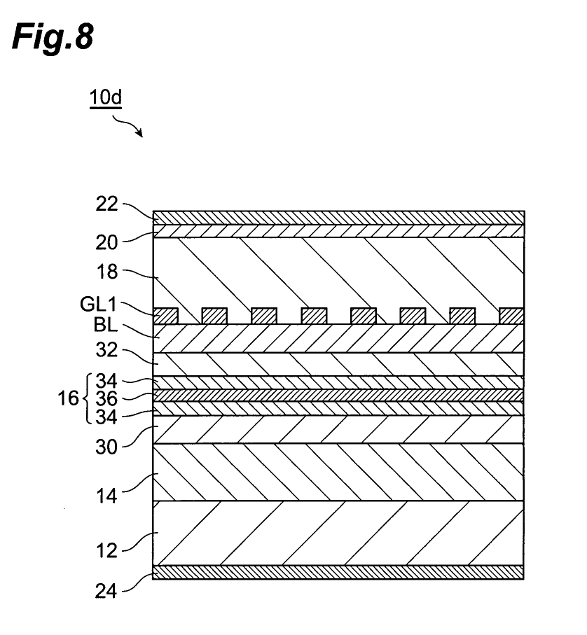

FIG. 7 is a perspective view showing schematically a semiconductor optical device according to a fifth embodiment. FIG. 8 is a cross-sectional view along the line VIII-VIII in FIG. 7. In the semiconductor optical device 10d in FIG. 7 and FIG. 8, in addition to the structure of the semiconductor optical device 10c according to the fourth embodiment, the cladding layer 18 comprises a ridge section 19 and further comprises a current blocking region 38 of first conductivity type (n-type) that is provided between the cladding layer 18 and the contact layer 20 so as to bury the ridge section 19. A current throttling structure is formed by the ridge section 19 and current blocking region 38. Also, the active layer 16 has a quantum well structure, comprising well layers 34 and barrier layers 36 alternately stacked.

Preferably the current blocking region 38 is made of semiconductor material lattice-matched to GaAs. Also, in order to confine light in the ridge section 19, preferably the refractive index of the current blocking region 38 is smaller than the refractive index n₁ of the cladding layer 18. If for example the cladding layer 18 is made of GaInP, material such as for example AlGaAs or AlGaInP, which is of lower refractive index than this, is employed as the semiconductor material constituting the current blocking region 38. For example Se or Si is preferably employed as the n-type dopant of the current blocking region 38.

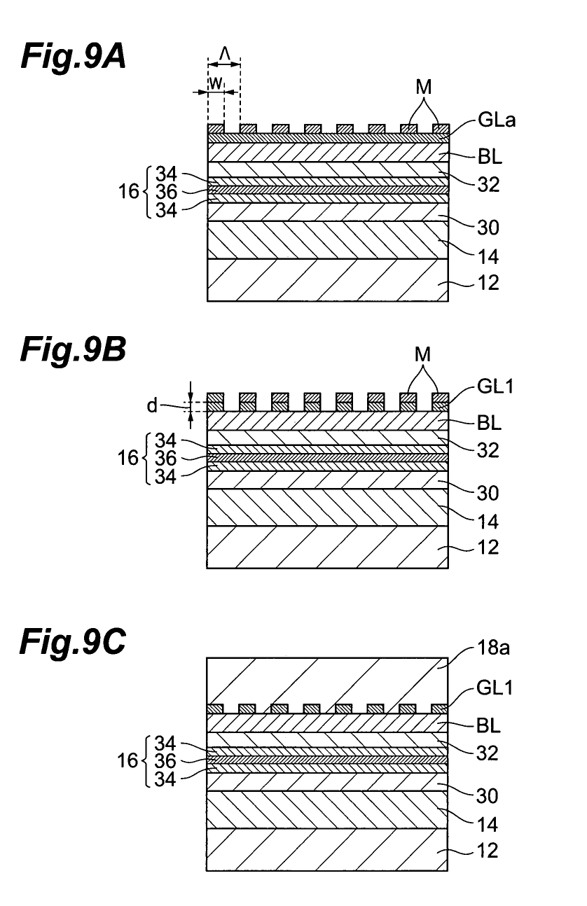

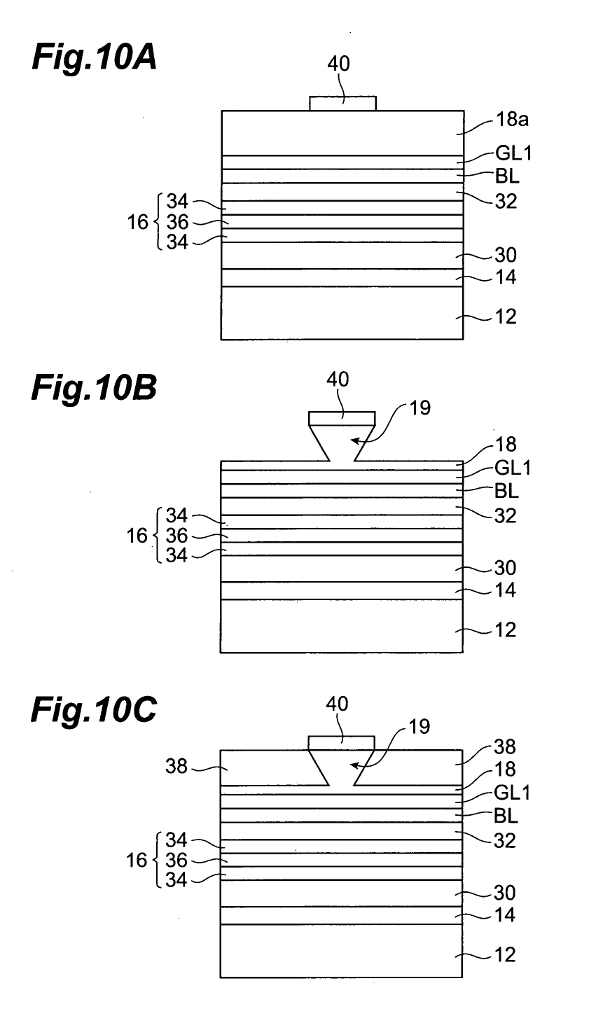

FIGS. 9A to 9C are cross-sectional views showing schematically steps in a method of manufacturing a semiconductor optical device according to the fifth embodiment. FIGS. 10A to 10C are views showing schematically steps in a method of manufacturing a semiconductor optical device according to the fifth embodiment. The method of manufacture of a semiconductor optical device 10d is described below.

First of all, as shown in FIG. 9A, a cladding layer 14, optical confinement layer 30, well layer 34, barrier layer 36, well layer 34, optical confinement layer 32, intermediate layer BL and III-V compound semiconductor layer GLa are formed in that order on the GaAs substrate 12. These layers may be formed using crystal growth methods such as the MBE method, OMVPE method or LPE method. For example if the OMVPE method is employed, metal organic compound such as for example TEG, TMG, TMI or TMA may suitably be employed as the group III source material. Hydride gases such as for example AsH₃ or PH₃ may suitably be employed as the group V source material. For example DMHy may suitably be employed as the N source material. For example Se or Si may suitably be employed as the n type dopant. For example Zn may suitably be employed as the p type dopant.

In addition, a resist mask M arranged periodically with prescribed pitch Λ is formed on the III-V compound semiconductor layer GLa. The resist mask M is preferably has a striped configuration. Preferably the width W of the resist mask M is suitably adjusted such that the coupling coefficient of the diffraction grating is the optimum value for oscillation of the DFB laser. When forming the resist mask M, for example an holographic exposure method or EB exposure method may be employed.

Next, as shown in FIG. 9B, wet etching or dry etching of the III-V compound semiconductor layer GLa is performed using the resist mask M. In this way, a diffraction grating layer GL1 is obtained. In this process, the intermediate layer BL preferably functions as an etching stop layer. In this case, etching is stopped without fail at the time-point where the etching has reached the intermediate layer BL, even if the etching rate fluctures depending on the position, or it changes every time the optical device 10d is fabricated. As a result, reproducibility of the thickness d of the diffraction grating layer GL1 and its uniformity with position are improved, so that reproducibility and uniformity of the light emission performance of the semiconductor optical device 10d are improved.

After removal of the resist mask M, as shown in FIG. 9C, a cladding layer 18a is grown on the diffraction grating layer GL1. The cladding layer 18a is grown such as to bury the concave sections of the diffraction grating layer GL1.

Next, as shown in FIG. 10A, a dielectric mask 40 that is patterned so as to correspond to the shape of the top face of the ridge section 19 is formed on the cladding layer 18a. The dielectric mask 40 is made of for example SiN or SiO₂.

Next, as shown in FIG. 10B, a cladding layer 18 having a ridge section 19 is formed by dry etching or wet etching of the cladding layer 18a using the dielectric mask 40.

Next, as shown in FIG. 10C, the current blocking region 38 is grown on the cladding layer 18 so as to bury the ridge section 19.

After removal of the dielectric mask 40, as shown in FIG. 7 and FIG. 8, a contact layer 20 is grown on the ridge section 19 and current blocking region 38. An electrode 22 is then formed on the contact layer 20 and an electrode 24 is formed on the back face of the GaAs substrate 12 using for example an evaporation method or sputtering method. In this way, a semiconductor optical device 10d is manufactured.

It should be noted that it would also be possible to employ for example benzocyclobutene (BCB), polyimide or semi-insulating semiconductor as the material of the current blocking region 38. Also, instead of the current blocking region 38, the side faces of the ridge section 19 could be covered with an insulating film of for example SiN or SiO₂. In addition, when etching the cladding layer 18a, a mesa section could be formed by etching as far as the active layer 16 and this mesa section then buried by a semiconductor region having a heterojunction.

While suitable embodiments of the present invention have been described in detail above, the present invention is not restricted to the above embodiments.

For example, the semiconductor optical devices 10, 10a, 10b, 10c, 10d are not restricted to semiconductor lasers but could be for example a semiconductor optical amplifier device, an electro-absorption type optical modulating device, or a semiconductor optical integrated device obtained by integrating these with a semiconductor laser. In each of these cases, with the structure of the present invention, the light that is emitted from the active layer can be very strongly confined in the diffraction grating layer, so light emission efficiency is improved.

With the present invention, a semiconductor laser is provided having excellent oscillation performance and high reproducibility and yield.

What is claimed is:

1. A semiconductor optical device comprising:
an active layer made of III-V compound semiconductor containing Ga, As and N;
a diffraction grating layer which is made of III-V compound semiconductor and is provided on the active layer; and
a cladding layer which is made of III-V compound semiconductor and is provided on the diffraction grating layer,
wherein the refractive index of the cladding layer is smaller than the refractive index of the diffraction grating layer.

2. The semiconductor optical device according to claim 1, further comprising a first intermediate layer which is made of III-V compound semiconductor and is provided between the diffraction grating layer and the cladding layer.

3. The semiconductor optical device according to claim 2, wherein the first intermediate layer includes a first semiconductor layer and a second semiconductor layer alternately stacked, and
wherein the band gap energy of the first semiconductor layer is different from the band gap energy of the second semiconductor layer.

4. The semiconductor optical device according to claim 1, further comprising a second intermediate layer which is made of III-V compound semiconductor and is provided between the active layer and the diffraction grating layer,
wherein the refractive index of the second intermediate layer is smaller than the refractive index of the diffraction grating layer.

5. The semiconductor optical device according to claim 1, further comprising a second intermediate layer which is made of III-V compound semiconductor and is provided between the active layer and the diffraction grating layer,
wherein the etching rate of the second intermediate layer is smaller than the etching rate of the diffraction grating layer.
